(19) United States
(12) Patent Application Publication
(10) Pub. No.: US 2024/0372543 A1
(43) Pub. Date: Nov. 7, 2024

(54) MULTIPHASE N-CHANNEL HIGH-SIDE SWITCH FOR GaN INTEGRATED CIRCUITS

(71) Applicant: Efficient Power Conversion Corporation, El Segundo, CA (US)

(72) Inventors: Michael Chapman, Long Beach, CA (US); Edward Lee, Fullerton, CA (US); John Glaser, Niskayuna, NY (US); Ravi Ananth, Laguna Niguel, CA (US)

(73) Assignee: Efficient Power Conversion Corporation, El Segundo, CA (US)

(21) Appl. No.: 18/653,156

(22) Filed: May 2, 2024

Related U.S. Application Data
(60) Provisional application No. 63/499,588, filed on May 2, 2023.

(51) Int. Cl. H03K 17/06; H03K 3/03; H03K 17/687

(52) U.S. Cl. CPC H03K 17/063; H03K 3/0315; H03K 17/687; H03K 2217/0063

(57) ABSTRACT

A power supply switch for a gallium nitride integrated circuit. The switch includes two or more parallel n-channel transistor switches (FETs). The FETs are controlled by AC gate waveforms of different phases. The use of multiple AC-controlled FETs allows effective DC operation of a supply switch without requiring a second DC supply voltage.

### CROSS-REFERENCE TO RELATED APPLICATION

This application claims the benefit of U.S. Provisional Application No. 63/499,588, filed May 2, 2023, the disclosure of which is incorporated by reference herein in its entirety.

### BACKGROUND OF THE INVENTION

### 1. Field of the Invention

The present invention relates to a power supply switch for a gallium nitride integrated circuit.

### 2. Description of the Related Art

A high-side switch in a circuit generally refers to a switch where one terminal of the switch is connected to a high potential, and a load or other circuitry is at the other terminal of said switch. A high-side switch is often employed when it is necessary to disconnect a circuit from its power supply, generally to disable the operation of the part or to save current.

A p-channel FET is one of the most common implementations of a high-side switch, as shown in FIG. 1. This approach is convenient since the FET gate voltage is always between GND and VDD.

However, in some semiconductor processes, for example GaN processes, p-channel devices are not generally available or have poor performance. For a supply-side switch, the only available device is usually a n-channel FET. This is less convenient, because to turn the FET on, its gate voltage must be above VDD by more than one FET threshold voltage (V_{TH}). This requires generation of a DC supply voltage above VDD. As shown in FIG. 2, this can be accomplished by providing a second, higher voltage supply VDD2.

As an alternative to a second voltage supply, a charge pump can be used to generate the second supply voltage internally to the IC, as shown in FIG. 3. Efficient charge pumps require the use of diodes with a low forward voltage (Vr). In GaN technologies, the most readily available diode is a FET with the gate and drain tied together, as shown in FIG. 4. The forward voltage of this device is approximately equal to one gate threshold. This is on the order of several volts, compared to approximately 0.2V for a Schottky diode. That effective forward diode voltage is prohibitively high for the implementation of an efficient charge pump circuit.

Accordingly, it would desirable to provide a circuit without the disadvantages described for each of the above supply-side switch schemes.

### SUMMARY OF THE INVENTION

The present invention advantageously eliminates the need for a second DC supply for the gates of the n-channel supply-side FET switches. Instead, multiple FETs are connected in parallel and driven with AC signals of different phases, effectively creating a second DC supply with minimal ripple. At any given time, one of the switches is always on. The advantage of the present invention is that it is relatively simple to create several AC voltage waveforms of multiple phases with sufficient amplitude to turn the FET switches on.

More specifically, the present invention is a multiphase switch connected between a DC voltage and a circuit to be powered by a higher DC voltage, i.e., higher by more than the threshold voltage of the power FET of the circuit. The multiphase switch comprises a plurality of n-channel FETs disposed in parallel between the DC voltage and the circuit to be powered by the higher DC voltage, where the gates of the n-channel FETs are driven by AC waveforms of different phases to generate the higher DC voltage for the circuit.

In a preferred embodiment, the multiphase switch of the present invention comprises four n-channel FETs disposed in parallel.

In one embodiment, the circuit to be powered comprises the high side switch of a half bridge circuit.

In another embodiment, the circuit to be powered comprises a bootstrap inverter circuit.

In yet another embodiment, the circuit to be powered comprises a cascaded bootstrap inverter circuit.

A ring oscillator is preferably used to generate the AC waveforms having different phases that are used to drive the gates of the paralleled n-channel FETs.

The multiphase switch of the present invention is preferably implemented in GaN technology with GaN FETs, and incorporated in a GaN integrated circuit.

The above and other preferred features described herein, including various novel details of implementation and combination of elements, will now be more particularly described with reference to the accompanying drawings and pointed out in the claims. It should be understood that the particular methods and apparatuses are shown by way of illustration only and not as limitations of the claims. As will be understood by those skilled in the art, the principles and features of the teachings herein may be employed in various and numerous embodiments without departing from the scope of the claims.

### BRIEF DESCRIPTION OF THE DRAWINGS

The features, objects, and advantages of the present disclosure will become more apparent from the detailed description set forth below when taken in conjunction with the drawings, in which like reference characters identify correspondingly throughout and wherein:

FIG. 1 shows a prior art P-channel high-side supply switch.

FIG. 2 shows a prior art N-channel high-side supply switch.

FIG. 3 shows a simple prior art diode charge pump.

FIG. 4 shows a GaN FET diode implementation.

FIG. 5 shows the multiphase n-channel high-side switch of the present invention.

FIG. 6 shows the two-phase high-side n-channel switch of the present invention, with example gate waveforms.

FIG. 7 is a waveform diagram with the two-phase high-side switch waveforms superimposed, showing the IC-side supply ripple and the phase transition region.

FIG. 8 shows a quadrature (four-phase) supply-side n-channel switch.

FIG. 9 shows the gate waveforms for the quadrature switch of FIG. 8.

FIG. 10 shows the quadrature switch gate waveforms of FIG. 9 superimposed to show the resulting IC-side supply ripple.

FIG. 11 shows the quadrature supply switch waveforms for both “enabled” and “disabled” states.

FIG. 12 shows a ring oscillator configured to generate AC waveforms, and appropriate taps for generating quadrature switching waveforms.

FIG. 13 shows a conventional bootstrapped n-channel inverter.

FIG. 14 shows the driver waveforms for the conventional bootstrapped n-channel driver of FIG. 13.

FIG. 15 shows a bootstrapped n-channel inverter with quadrature bootstrap-charging switches.

FIG. 16 shows the waveforms for the bootstrapped n-channel inverter of FIG. 15.

FIG. 17 shows the two-stage cascaded bootstrap inverter of U.S. Pat. No. 10,790,811.

FIG. 18 shows the two-stage cascaded bootstrap inverter of FIG. 17 implemented with the multiphase bootstrap charging switches of the present invention.

FIG. 19 shows a bootstrapped inverter with multiphase switches as pull-up switches on the output node.

FIG. 20 shows an inverter with multiphase load pullup.

FIG. 21 shows a single N-channel high side supply switch controlled with multiple clock phase signals.

FIG. 22 is a waveform diagram showing the control signals and multiphase clock signals connected to FET 1, . . . , FETn for turning on the single N-channel high side supply switch of FIG. 21.

FIG. 23 shows a multi-stage cascaded bootstrapping inverter for generating each pair of control signal Vgj and source signal Vsj of FIG. 22.

FIG. 24 is a waveform diagram showing the waveforms of the multi-stage cascaded bootstrapping inverter of FIG. 23.

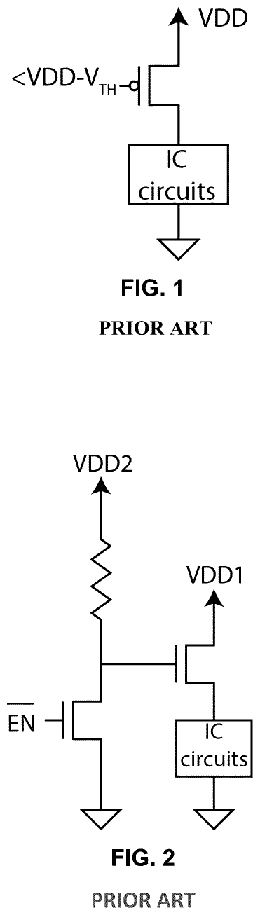

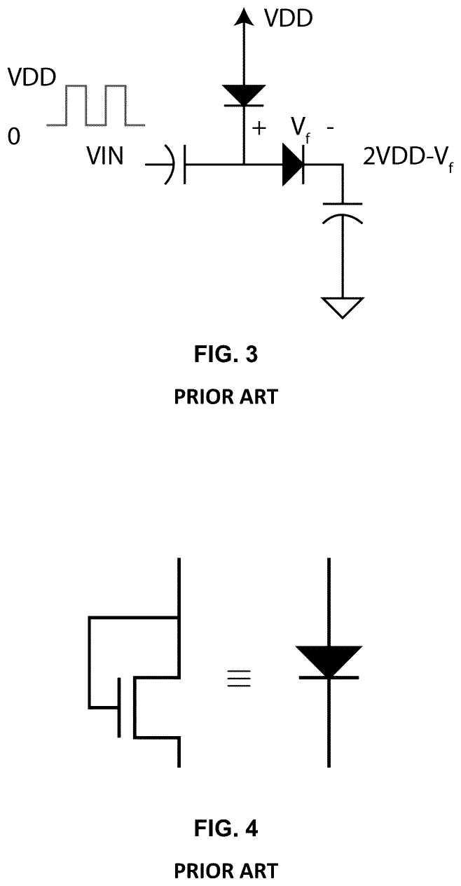

### DETAILED DESCRIPTION OF THE PREFERRED EMBODIMENTS

In the following detailed description, reference is made to certain embodiments. These embodiments are described with sufficient detail to enable those skilled in the art to practice them. It is to be understood that other embodiments may be employed and that various structural, logical, and electrical changes may be made. The combinations of features disclosed in the following detailed description may not be necessary to practice the teachings in the broadest sense, and are instead taught merely to describe particularly representative examples of the present teachings.

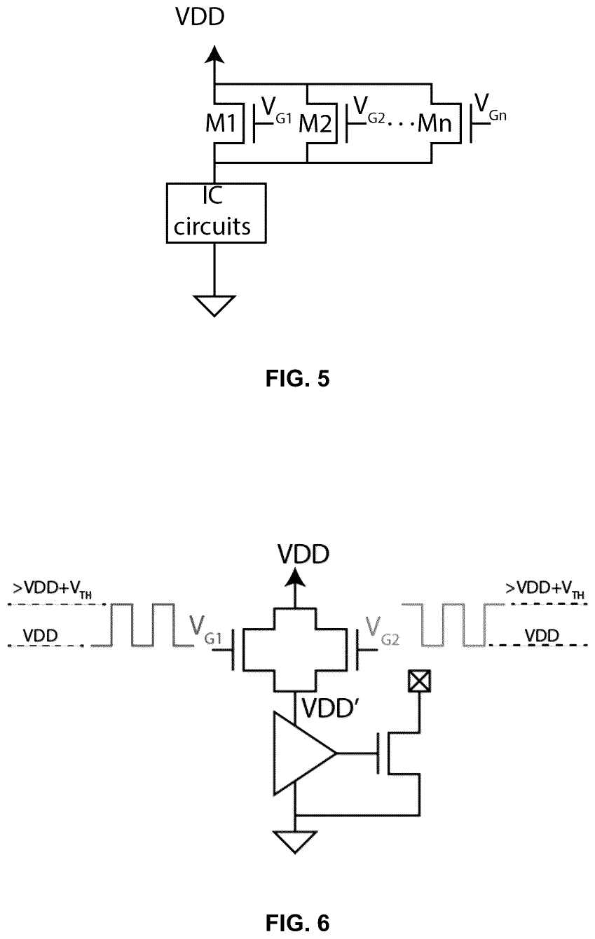

The present invention, in the embodiments and applications described below, advantageously avoids the need for a DC supply for the gates of the n-channel supply-side FET switches. Instead, in accordance with the present invention, as shown in FIG. 5, multiple FETs are connected in parallel and driven with AC signals of different phases. At any given time, one of the FETs is always on. The advantage of the present invention is that it is relatively simple to create several AC voltage waveforms of multiple phases with sufficient amplitude to turn the FET switches on. Accordingly, the present invention avoids the difficulties in creating a second voltage supply to drive the high-side n-channel switch gates, as previously described.

The present invention provides a multiphase n-channel high side switch for gallium nitride (GaN) integrated circuits, and preferably comprises GaN components, including GaN FETs.

FIG. 6 shows a simple two-phase parallel switch embodiment of the present invention. The two-phase switch of FIG. 6 is driven by two opposite-phase voltage waveforms. Since FET 1 is always on when FET 2 is off and vice-versa, an effective DC switch is created by the logical “OR” effect provided by the two parallel FETs: FET 1 and FET 2.

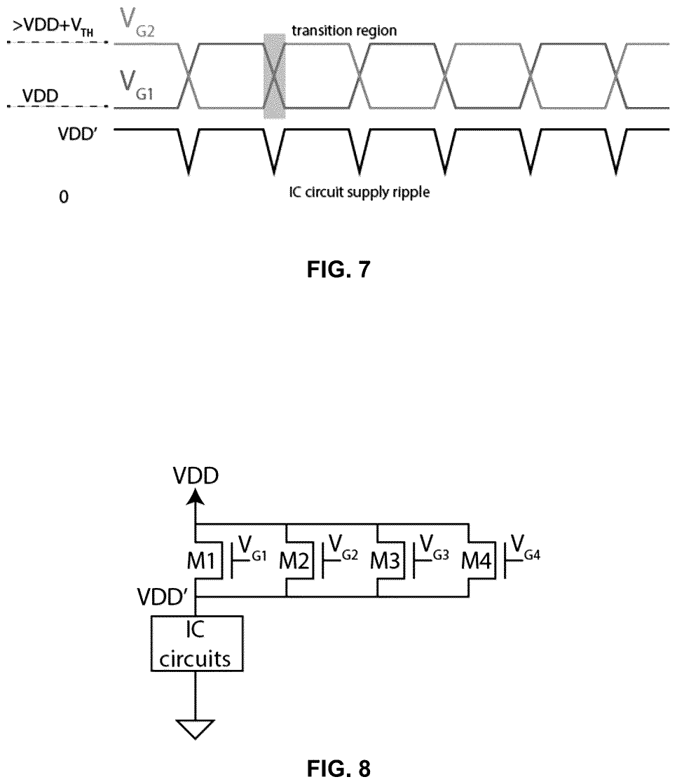

One potential drawback with the two-phase approach is that when the waveforms are in the transition region, neither one is fully “on”. As shown in FIG. 7, this results in an undesirable amount of ripple on the supply voltage reaching the IC circuits. One solution is to increase the duty cycle of each phase such that a phase transition of one switch does not occur simultaneously with at least one other phase. In the case of a two-phase switch, the resultant duty cycle of each phase would be at least 0.5+tₜᵣₐₙ/T, where tₜᵣₐₙ is the transition time of the phase waveform and T is the period of the phase waveform. However, in some cases, increasing the duty cycle of each phase can complicate the circuit design.

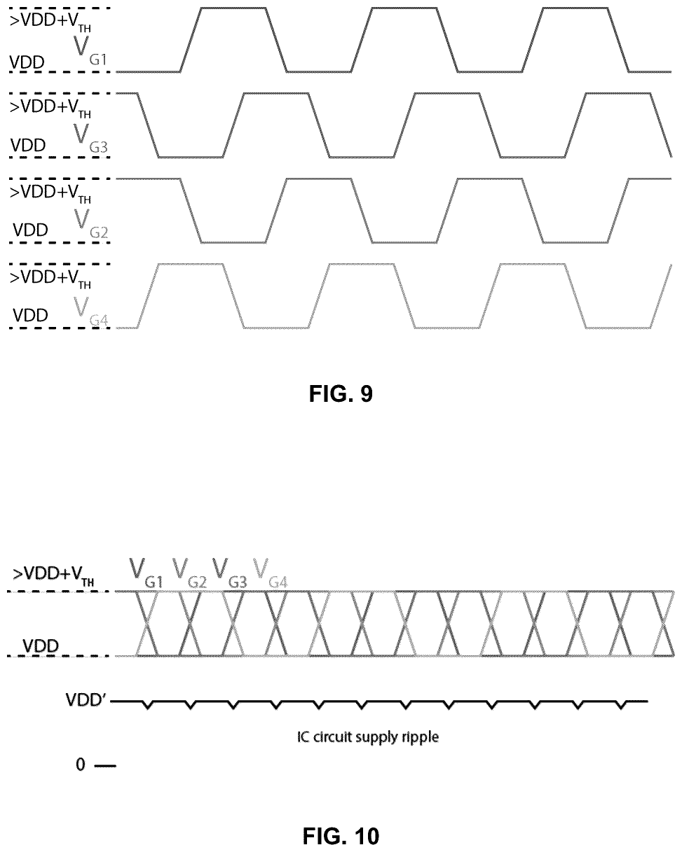

A significant improvement to the two-phase concept is attained by doubling the number of phases to four phases, using four switches, as shown in FIGS. 8 and 9. This reduces the ripple on VDD′ dramatically because, when any phase is in a transition state, at least one FET is always fully on. This ensures a strong conduction path for load current throughout the entire switching cycle. The improved ripple, due to one phase always being fully on, is shown in FIG. 10.

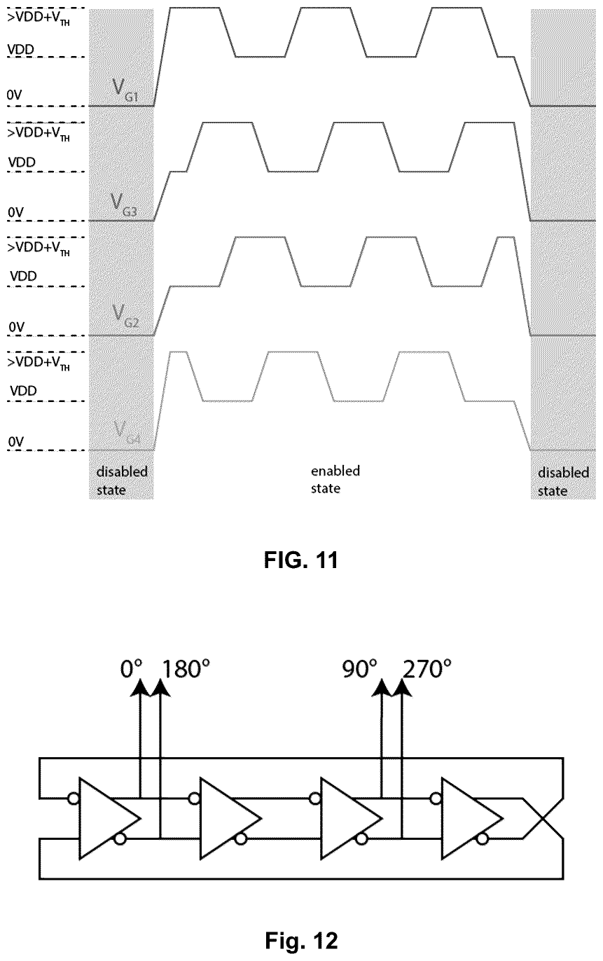

Referring now to the quadrature switch waveforms of FIG. 11, in the “enabled” state, the switch gate waveforms alternate between two voltages: VDD, and some higher voltage that exceeds VDD+V_{TH} (where V_{TH} is the threshold of the n-channel switching FET). In the “disabled” state, the gate must be pulled fully down to 0V or some current will continue to leak through the IC circuitry.

As shown in FIG. 12, a ring oscillator may be used to generate the four phase AC waveforms, with the four phases provided by using different “taps” from the ring oscillator circuit.

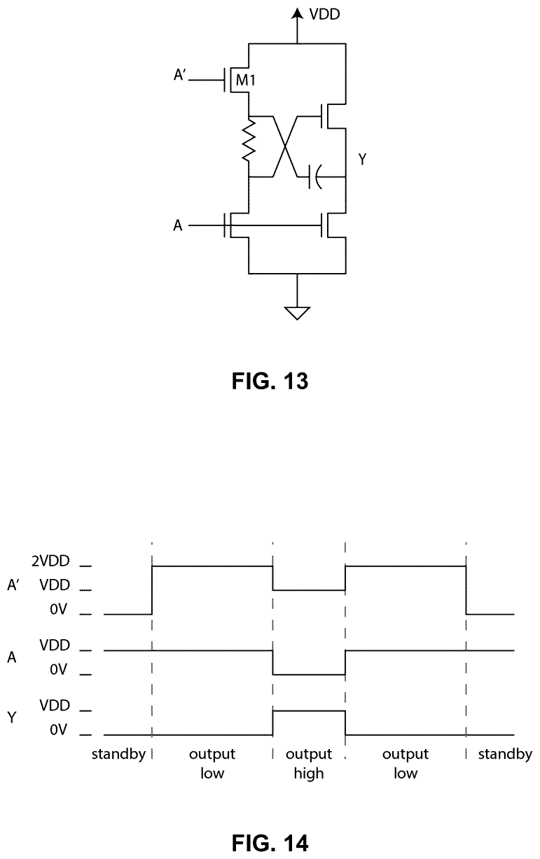

The multiphase switch of the present invention has a number of uses and applications. For example, FIGS. 13 and 14 show a conventional bootstrapped n-channel inverter driver, and the respective waveforms. In the “charging” state, FET 1 is “on”, and the “Y” node is low. The gate of FET 1 must be at a DC voltage higher than VDD+V_{TH}. As described earlier, generating a DC voltage that is above the supply voltage is inconvenient.

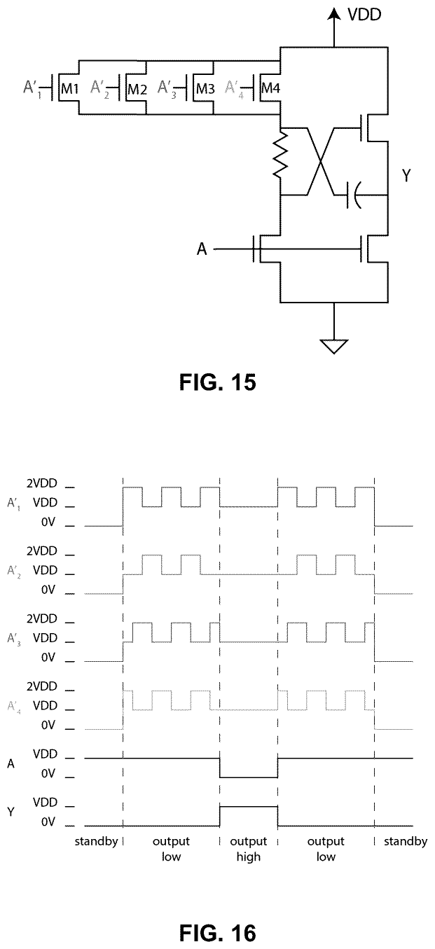

By replacing FET 1 with a multiphase switch array (FET 1-FET 4) of the present invention, as shown in FIG. 15, the need for a second voltage supply is eliminated. The waveforms during operation of the bootstrapped inverter of FIG. 15 are shown in FIG. 16.

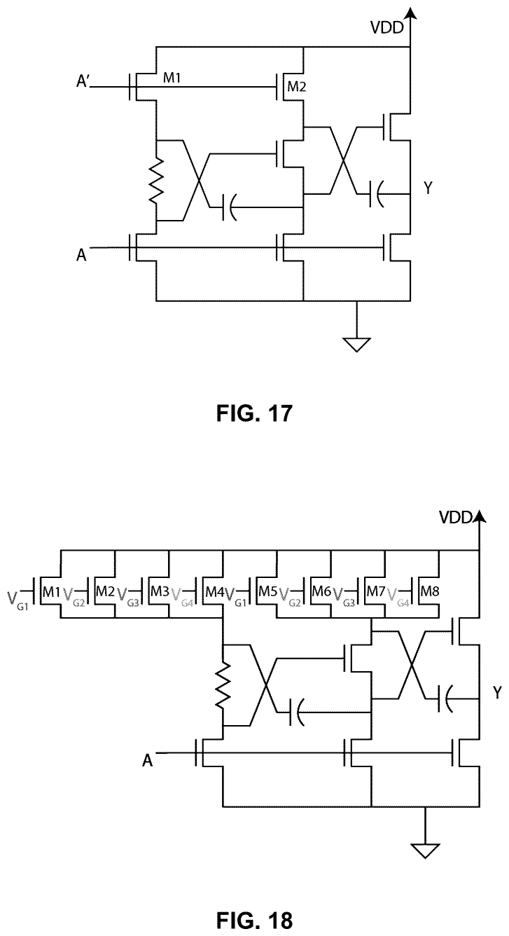

The multiphase high-side switch technology of the present invention can also be implemented in a cascaded bootstrap inverter, such as the two-stage cascaded bootstrap converter shown in FIG. 17, and described in U.S. Pat. No. 10,790,811. The implementation of the multiphase technology of the present invention in the cascaded inverter is shown in FIG. 18, and advantageously eliminates the second supply requirement as in prior examples.

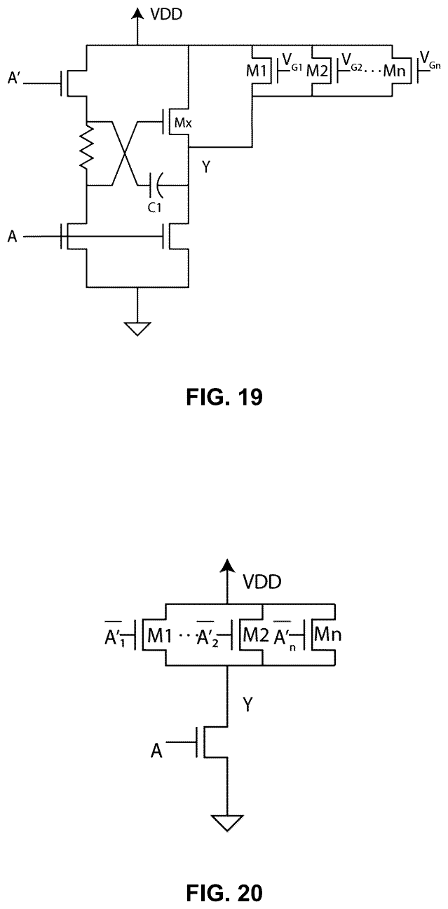

FIG. 19 shows a bootstrapped inverter with multiphase switches as pullup switches on the output node Y. The advantage of the bootstrapped topology is that it provides a strong pullup device in FETx, resulting in fast transition times. The topology has a drawback, however, in that the output node Y can only be held “high” for a finite duration. Eventually, the charge on C1 that holds the gate of FETx above VDD will discharge. The gate of FETx will then leak to VDD or below and the Y net could fall into a “low” or indeterminate state.

In this case, it can be beneficial to employ a multiphase switch in accordance with the present invention to hold the output node Y in the “high” output state. The gates of the switches must be pulled to ground potential when the Y node is in the “low” output state.

Another possible application of the multiphase switch of the present invention is in the pullup component of an inverter stage, as shown in FIG. 20. In this embodiment, the multiphase switch comprises the entire pullup element that provides the conductive path between the load and VDD.

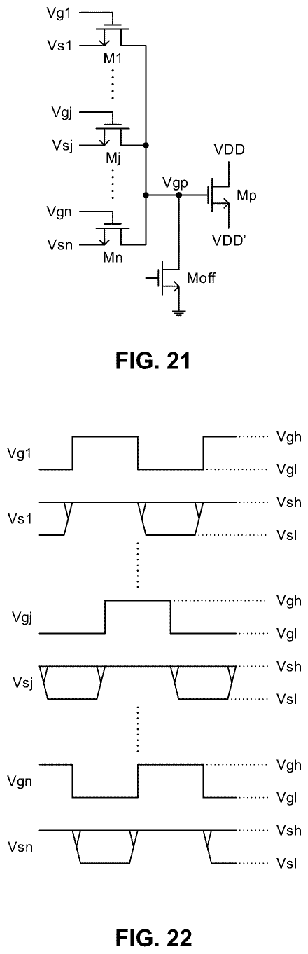

An alternative structure to realize an N-channel high side supply switch is shown in FIG. 21. In this structure, the drain and source terminals of a single N-channel supply switch, FETp, are connected between VDD and VDD′. The gate terminal, Vgp, is connected to FEToff, and n control N-FETs—FET 1, . . . , FETn, where n is ≥1. The gates of FET 1, . . . , FETn are controlled by multiphase control signals—Vg1, . . . , Vgn, respectively. The sources of FET 1, . . . , FETn are connected to multiphase source signals-Vs1, . . . , Vsn, respectively.

When FETp is desired to be off, FEToff is on and FET 1, . . . , FETn, are off with all the multiphase control signals—Vg1, . . . , Vgn switched to ground such that Vgp is pulled to ground.

When FETp is desired to be on, FEToff is off and the control N-FETs—FET 1, . . . , FETn, are switched on/off according to the multiphase control signals—Vg1, . . . , Vgn as shown in FIG. 22, such that individual multiphase source signals—Vs1, . . . , Vsn are switched to Vgp for keeping FETp on. To turn on FETp, Vgp has to be higher than VDD+Vth where Vth is the threshold voltage of FETp. As a result, the high source voltage level, Vsh, for Vs1, . . . , Vsn must satisfy the following condition.

$$Vsh > VDD + Vth \qquad ( 1 )$$

According to the multiphase control signals—Vg1, . . . , Vgn, for the control N-FETs that need to be on, the high gate voltage level, Vgh, for Vg1, . . . , Vgn must satisfy the following condition.

$$Vgh > Vsh + Vth \qquad ( 2 )$$

For the other control N-FETs that need to be off, the low gate voltage level, Vg1, for Vg1, . . . , Vgn must satisfy the following condition.

$$Vgl < Vsl - Vth \qquad ( 3 )$$

If there is only one control N-FET with n=1, the gate voltage of FETp, Vgp, is assumed to be held approximately equal to Vsh by the gate capacitance (or a dedicated capacitor connected to Vgp) to keep FETp to be on when the control N-FET is off.

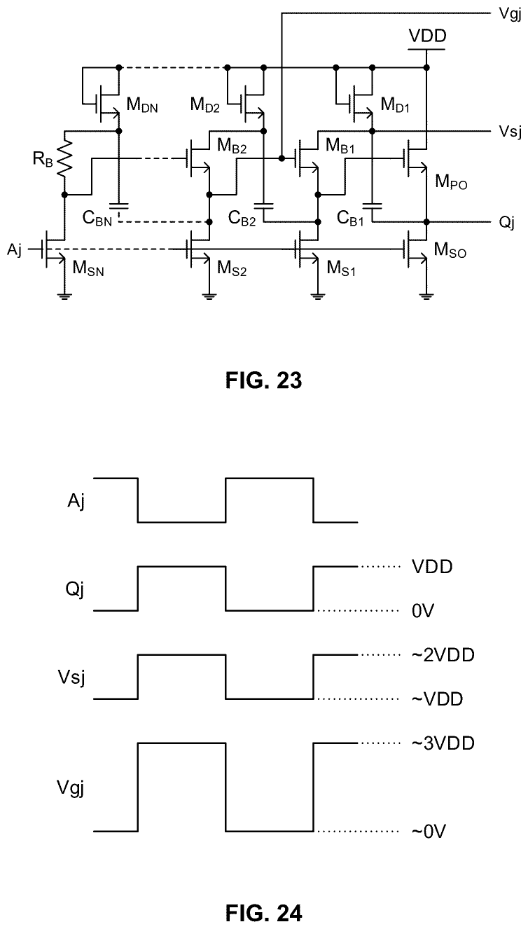

One way to generate the multiphase control signals and the multiphase source signals is to use multi-stage cascade bootstrapping inverters described in U.S. Pat. No. 10,790,811. Each pair of control signals—Vgj and source signal—Vsj that are connected to the control N-FET—FETj can be generated from one multi-stage cascade bootstrapping inverter as shown in FIG. 23. The conditions (1), (2) and (3) can be satisfied using this circuit.

When Aj is logic 0, FET_{S1}, . . . , FET_{SN} and FET_{SO} are off. C_{BN} will charge up the gate of FET_{B2} through R_{B}, and FET_{B2} will be turned on. In turn, C_{B2} will charge up the gate of FET_{B1} through FET_{B2}, and hence, FET_{B1} will be turned on. Similarly, C_{B1} will charge up the gate of FET_{PO} through FET_{B1}. Hence, FET_{PO} will be turned on, and Qj will be driven up to VDD. Since the voltage across C_{B1} will maintain approximately VDD, Vsj will be ˜2VDD. Similarly, since the voltage across C_{B2} will maintain approximately VDD, Vgj (equal to Vsj plus voltage across C_{B2}) will be ˜3VDD and the corresponding control N-FET (FETj in FIG. 21) connected to Vgj and Vsj will be turned on. Vsj (equal to ˜2VDD) will be passed to the gate of the supply switch FET (FETp in FIG. 21) to keep FETp on.

The above description and drawings are only to be considered illustrative of specific embodiments, which achieve the features and advantages described herein. Modifications and substitutions to specific process conditions can be made. Accordingly, the embodiments of the invention are not considered as being limited by the foregoing description and drawings.

What is claimed is:

1. A multiphase switch connected between a DC voltage and a circuit to be powered by a higher DC voltage, comprising a plurality of n-channel FETs disposed in parallel between the DC voltage and the circuit to be powered by the higher DC voltage, wherein the n-channel FETs each have a gate, and wherein the gates of the n-channel FETs are driven by AC waveforms of different phases.

2. The multiphase switch of claim 1, comprising four n-channel FETs disposed in parallel.

3. The multiphase switch of claim 1, wherein the circuit comprises the high side switch of a half bridge circuit.

4. The multiphase switch of claim 1, wherein the circuit comprises a bootstrap inverter circuit.

5. The multiphase switch of claim 1, wherein the circuit comprises a cascaded bootstrap inverter circuit.

6. The multiphase switch of claim 1, wherein the circuit comprises a FET having source and drain terminals connected, respectively to the DC voltage and the higher DC voltage.

7. The multiphase switch of claim 1, wherein the multiphase switch comprises pull up switches on an output node of a bootstrapped inverter.

8. The multiphase switch of claim 1, wherein the multiphase switch comprises a pull up component of an inverter stage, and provides a conductive path between the DC voltage and a load.

9. The multiphase switch of claim 1, further comprising a ring oscillator to generate the AC waveforms.

10. The multiphase switch of claim 1, implemented in GaN technology with GaN FETs, and incorporated in a GaN integrated circuit.

11. The multiphase switch of claim 1, wherein the higher DC voltage is greater than the DC voltage plus a threshold voltage, and the AC waveforms transition between the DC voltage and the voltage greater than the DC voltage plus a threshold voltage to generate a supply voltage for the circuit at the higher DC voltage.
